(19) United States
(12) Patent Application Publication
(10) Pub. No.: US 2015/0108316 A1
(43) Pub. Date: Apr. 23, 2015

(54) PORTABLE SUPPORTING FRAME

(71) Applicants: Fu Tai Hua Industry (Shenzhen) Co., Ltd., Shenzhen (CN); HON HAI PRECISION INDUSTRY CO., LTD., New Taipei (TW)

(72) Inventors: TSUNG-SHAN HOU, New Taipei (TW); QIAN LEI, Shenzhen (CN)

(21) Appl. No.: 14/512,692

(22) Filed: Oct. 13, 2014

(30) Foreign Application Priority Data
Oct. 18, 2013 (CN) 201310488401.1

(51) Int. Cl. H05K 5/02; F16M 11/38; H05K 5/00

(52) U.S. Cl. CPC H05K 5/0204; H05K 5/0086; F16M 11/38
USPC 248/450

(57) ABSTRACT

A portable supporting frame includes a first, a second and a third supporting arm. The first supporting arm pivots on a first end portion of the second supporting arm, and the third supporting arm pivots on the second end portion of the second supporting arm. A number of stopper portions are arranged on a surface of the first supporting arm, and a free end portion of the third supporting arm can be engaged with one of the stopper portions when the portable supporting frame is unfolded, to form a triangular support to support an electronic device. A hook structure pivots relative to the first end portion of the second supporting arm, and can be rotated relative to the second supporting arm, to define a receiving space to provide a resistant platform against a bottom end portion of the electronic device.

### CROSS-REFERENCE TO RELATED APPLICATIONS

This application claims priority to Chinese Patent Application No. 201310488401.1 filed on Oct. 18, 2013, the contents of which are incorporated by reference herein.

### FIELD

The subject matter herein generally relates to portable supporting frames which can support electronic devices.

### BACKGROUND

A supporting frame is usually used for supporting an electronic device when the electronic device is in use.

### BRIEF DESCRIPTION OF THE DRAWINGS

Implementations of the present disclosure will now be described, by way of example only, with reference to the attached figures.

FIG. 1 is an isometric view showing a portable supporting frame in a folded state.

FIG. 2 is an exploded view of the portable supporting frame of FIG. 1.

FIG. 3 is an isometric view showing the portable supporting frame of FIG. 1 in an unfolded state.

FIG. 4 is an isometric view showing the portable supporting frame of FIG. 3 in use.

FIG. 5 is an isometric view showing the portable supporting frame of FIG. 1 not in use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Definitions that apply throughout this disclosure will now be presented.

The term “comprising” means “including, but not necessarily limited to”; it specifically indicates open-ended inclusion or membership in a so-described combination, group, series and the like. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder.

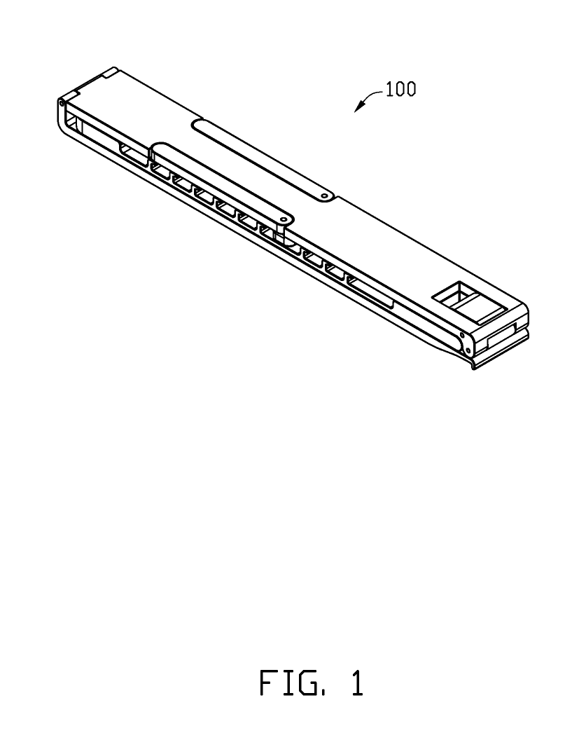

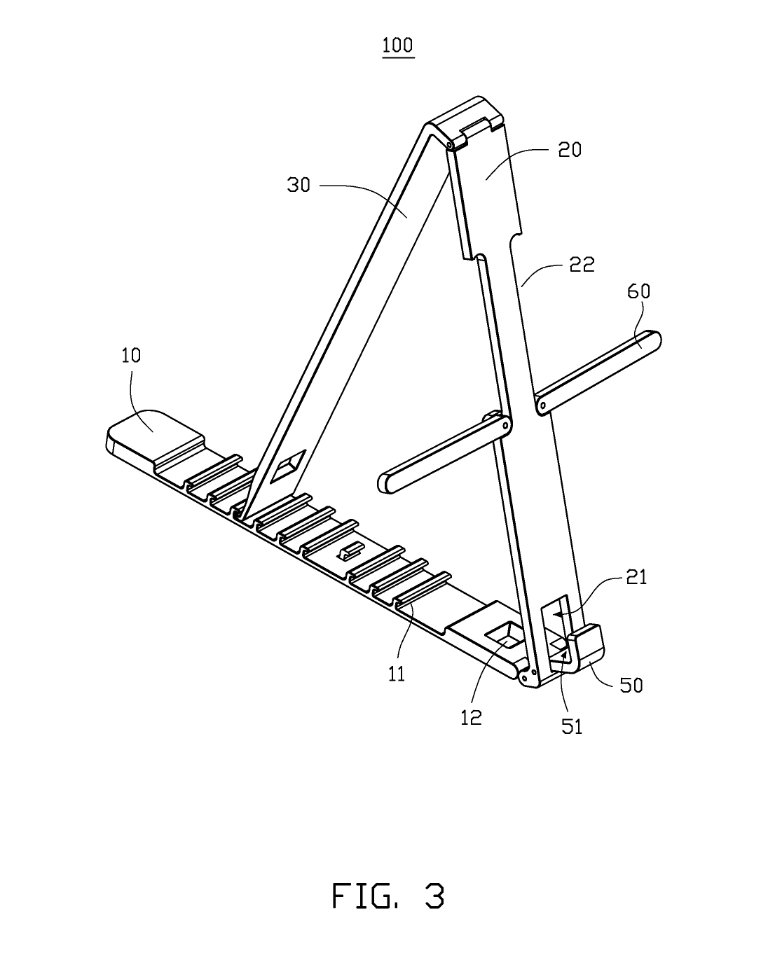

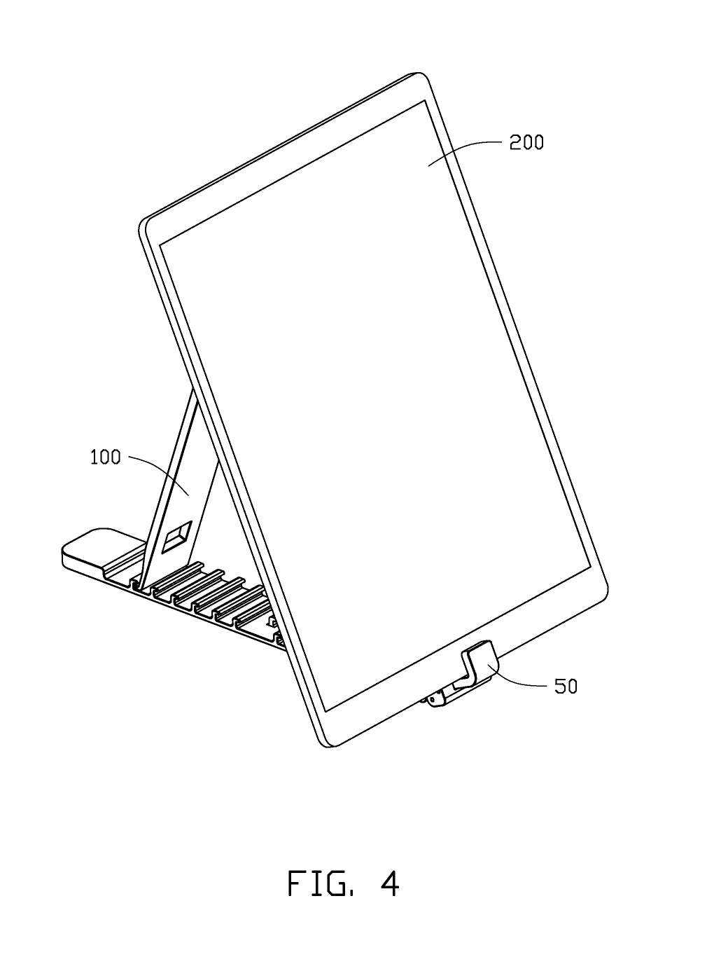

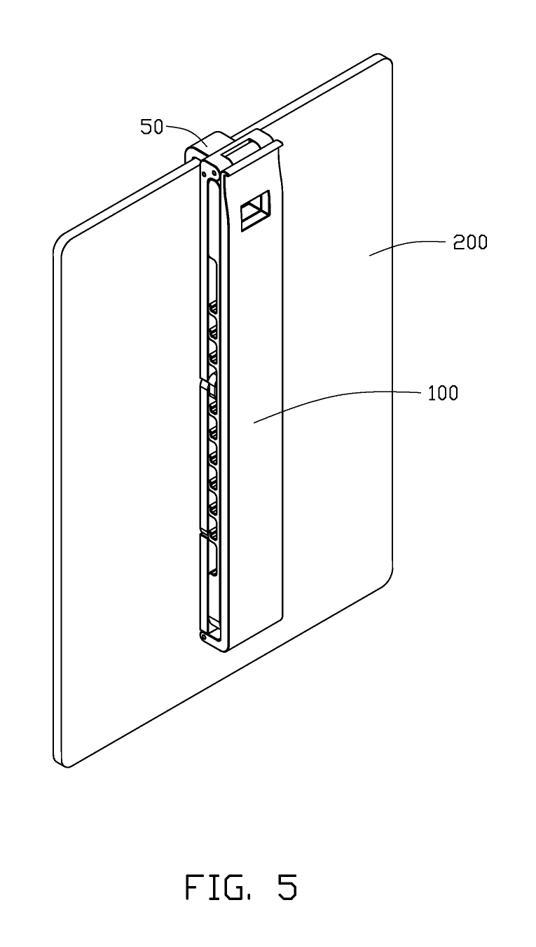

FIG. 1 illustrates a portable supporting frame 100 when not in use in a folded state. FIGS. 3 and 4 illustrate that the portable supporting frame 100 can be unfolded and used for supporting an electronic device 200. FIG. 5 illustrates that the portable supporting frame 100 can be clipped or hooked to the electronic device 200 when not in use.

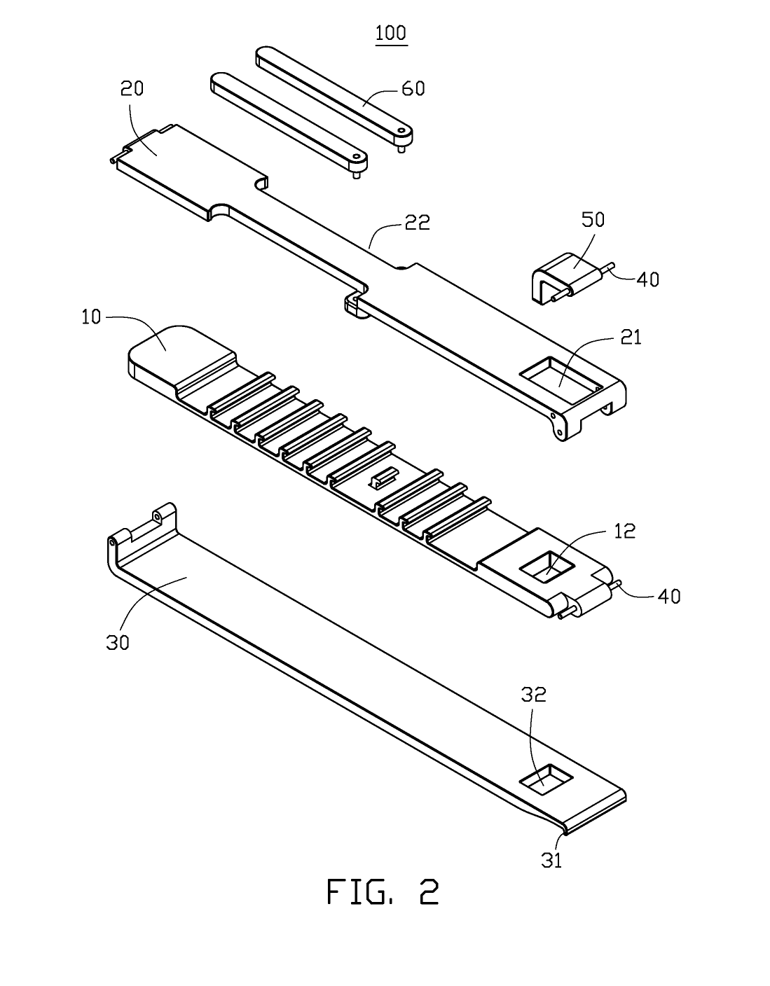

FIG. 2 illustrates that the portable supporting frame 100 includes a first supporting arm 10, a second supporting arm 20 and a third supporting arm 30. In at least one embodiment, the second supporting arm 20 includes a first end portion pivoting on a first end portion of the first supporting arm 10 via a rotation shaft 40, and the third supporting arm 30 includes a first end portion pivoting on a second end portion of the second supporting arm 20. FIG. 1 illustrates the first supporting arm 10 can be received between the second supporting arm 20 and the third supporting arm 30 in a folded state. In other embodiments, the third supporting arm 30 can be folded and received between the second supporting arm 20 and the first supporting arm 10. Thus, the portable supporting frame 100 is small and easy to carry.

FIGS. 2 and 3 illustrate that in at least one embodiment, the first supporting arm 10 includes a number of stopper portions 11 arranged on a surface, and a free end portion of the third supporting arm 30 is able to be engaged with one of the stopper portions 11 when the portable supporting frame 100 is unfolded, a substantially triangular support is formed with the portable supporting frame 100 to support the electronic device 200.

In at least one embodiment, each positioning portion 11 is substantially a hook extending from a surface of the first supporting arm 10 and bending toward the first end portion of the first supporting arm 10. A convex bar 31 extends from the free end portion of the third supporting arm 30 and is configured to be engaged with one of the stopper portions 11. In the illustrated embodiment, the convex bar 31 faces a free end portion of the first supporting arm 10 when the convex bar 31 is engaged with one of the stopper portions 11. An angle formed between the first supporting arm 10 and the second supporting arm 20 can be adjusted by the engagement of the convex bar 31 into different stopper portions 11.

In at least one embodiment, the portable supporting frame 100 further includes a hook structure 50. The hook structure 50 includes a first end portion pivoting on the first end portion of the second supporting arm 20 via a rotation shaft 40. The hook structure 50 is able to be rotated relative to the second supporting arm 20. When the first end portion of the hook structure 50 binds against the second supporting arm 20, the hook structure 50 cannot rotate further, therefore the range of rotation of the second supporting arm 20 is limited, and a receiving space 51 is defined between the hook structure 50 and the second supporting arm 20.

In the illustrated embodiment, the hook structure 50 is an L-shaped block. The receiving space 51 is configured to provide a resistant platform against a bottom end portion of the electronic device 200 when the electronic device 200 is resting on the portable supporting frame 100, stopping the electronic device 200 from sliding off the portable supporting frame 100.

When not in use, the portable supporting frame 100 can be folded as shown in FIG. 5, and the receiving space 51 enables the portable supporting frame 100 to be hooked or clipped to an edge of the electronic device 200, making the portable supporting frame 100 portable and easy to carry with the electronic device 200.

In at least one embodiment, the second supporting arm 20 defines a first through-hole 21 corresponding to the hook structure 50. The hook structure 50 pivots on two sides of the first through-hole 21 and is able to be received in the first through-hole 21 when the hook structure 50 is folded toward the second supporting arm 20.

In at least one embodiment, the first supporting arm 30 defines a second through-hole 12 corresponding to the hook structure 50, and when the hook structure 50 and the first supporting arm 10 are respectively folded toward the second supporting arm 20, the hook structure 50 is received in the second through-hole 12 through the first through-hole 21.

In at least one embodiment, the third supporting arm 30 defines a third through-hole 32 corresponding to the hook structure 50, and when the hook structure 50, the first supporting arm 10, and the third supporting arm 30 are respectively folded toward the second supporting arm 20, the hook structure 50 is received in the third through-hole 32 through the first through-hole 21 and the second through-hole 12.

In other embodiments, the hook structure 50 is also able to be received in the third through-hole 32 through the first through-hole 21, when the hook structure 50 and the third supporting arm 30 are respectively folded toward the second supporting arm 20. In other embodiments, the hook structure 50 is also able to be received in the second through-hole 12 through the first through-hole 21 and the third through-hole 32, when the hook structure 50, the third supporting arm 30 and the first supporting arm 10 are respectively folded toward the second supporting arm 20.

In at least one embodiment, the portable supporting frame 100 further includes a pair of supporting brackets 60 pivoting symmetrically on two sides of the second supporting arm 20 and away from the first end portion of the second supporting arm 20. The supporting brackets 60 are able to be rotated relative to the second supporting arm 20, to form a claw like structure with the second supporting arm 20 and the supporting brackets 60, allowing the electronic device 200 to rest stability on the portable supporting frame 100.

In the illustrated embodiment, a surface of each supporting bracket 60 facing the hook structure 50 is substantially flush with a surface of the second supporting arm 20 facing the hook structure 50. As such, the surfaces of the supporting brackets 60 and the surface of the second supporting arm 20 can cooperate to form a supporting plane, allowing the electronic device 200 to rest stability on the portable supporting frame 100.

In the illustrated embodiment, the second supporting arm 20 defines a pair of concave parts 22 on two symmetrical sides thereof corresponding to the supporting brackets 60. The concave parts 22 are configured to receive the supporting brackets 60 when the supporting brackets 60 are folded toward the second supporting arm 20. As such, the supporting brackets 60 can be small allowing the portable supporting frame 100 to be easily carried.

The embodiments shown and described above are only examples. Even though numerous characteristics and advantages of the present technology have been set forth in the foregoing description, together with details of the structure and function of the present disclosure, the disclosure is illustrative only, and changes may be made in the details, including in particular the matters of shape, size, and arrangement of parts within the principles of the present disclosure, up to and including the full extent established by the broad general meaning of the terms used in the claims.

What is claimed is:

1. A portable supporting frame comprising:
a first supporting arm comprising a plurality of stopper portions arranged on a surface;
a second supporting arm having a first end portion pivoting on a first end portion of the first supporting arm;
a third supporting arm having a first end portion pivoting on a second end portion of the second supporting arm, wherein a free end portion of the third supporting arm is able to be engaged with one of the stopper portions when the portable supporting frame is unfolded, thus a triangular support is formed with the portable supporting frame to support an electronic device; and
a hook structure having a first end portion pivoting relative to the first end portion of the second supporting arm, wherein the hook structure is able to be rotated relative to the second supporting arm, to define a receiving space between the hook structure and the second supporting arm, wherein the receiving space is configured to provide a resistant platform against a bottom end portion of the electronic device when the electronic device is resting on the portable supporting frame, stopping the electronic device from sliding off the portable supporting frame.

2. The portable supporting frame as described in claim 1, wherein the second supporting arm defines a first through-hole corresponding to the hook structure, and the hook structure pivots on two sides of the first through-hole and is able to be received in the first through-hole when the hook structure is folded toward the second supporting arm.

3. The portable supporting frame as described in claim 2, wherein the first supporting arm defines a second through-hole corresponding to the hook structure, and when the hook structure and the first supporting arm are respectively folded toward the second supporting arm, the hook structure is able to be received in the second through-hole through the first through-hole.

4. The portable supporting frame as described in claim 3, wherein the third supporting arm defines a third through-hole corresponding to the hook structure, and when the hook structure, the first supporting arm, and the third supporting arm are respectively folded toward the second supporting arm, the hook structure is able to be received in the third through-hole through the first through-hole and the second through-hole.

5. The portable supporting frame as described in claim 4, wherein the hook structure is able to be received in the third through-hole through the first through-hole, when the hook structure and the third supporting arm are respectively folded toward the second supporting arm.

6. The portable supporting frame as described in claim 4, wherein the hook structure is able to be received in the second through-hole through the first through-hole and the third through-hole, when the hook structure, the third supporting arm and the first supporting arm are respectively folded toward the second supporting arm.

7. The portable supporting frame as described in claim 1, wherein the hook structure is an L-shaped block.

8. The portable supporting frame as described in claim 1, further comprising a pair of supporting brackets pivoting symmetrically on two sides of the second supporting arm and away from the first end portion of the second supporting arm, wherein the supporting brackets are able to be rotated relative to the second supporting arm, to form a claw like structure with the second supporting arm and the supporting brackets, allowing the electronic device to rest stability on the portable supporting frame.

9. The portable supporting frame as described in claim 8, wherein a surface of each supporting bracket facing the hook structure is flush with a surface of the second supporting arm facing the hook structure.

10. The portable supporting frame as described in claim 8, wherein the second supporting arm defines a pair of concave parts on two symmetrical sides thereof corresponding to the supporting brackets, wherein the concave parts are configured to receive the supporting brackets when the supporting brackets are folded toward the second supporting arm.

11. The portable supporting frame as described in claim 1, wherein each of the plurality of stopper portions is a hook extending from a surface of the first supporting arm and bending toward the first end portion of the first supporting arm.

12. The portable supporting frame as described in claim 11, wherein a convex bar extends from the free end portion of the third supporting arm and is configured to be engaged with one of the stopper portions, wherein the convex bar faces a free end portion of the first supporting arm when the convex bar is engaged with one of the stopper portions.
